(19) United States
(12) Patent Application Publication
(10) Pub. No.: US 2024/0329085 A1
(43) Pub. Date: Oct. 3, 2024

(54) PROBE CARD

(71) Applicant: YOKOWO CO., LTD., Chiyoda-ku, TOKYO (JP)

(72) Inventor: Takeshi TODOROKI, Tomioka-shi, Gunma (JP)

(73) Assignee: YOKOWO CO., LTD., Chiyoda-ku, Tokyo (JP)

(21) Appl. No.: 18/578,025

(22) PCT Filed: Jul. 15, 2022
(86) PCT No.: PCT/JP2022/027830

§ 371 Date: Jan. 10, 2024

(30) Foreign Application Priority Data
Jul. 28, 2021 (JP) 2021-123029

(51) Int. Cl. G01R 1/073

(52) U.S. Cl. CPC G01R 1/07314

(57) ABSTRACT

A probe card including an insulating layer, a first conductor at least partially extending along a surface of the insulating layer, and a second conductor at least partially penetrating at least a portion of the insulating layer.

### TECHNICAL FIELD

The present invention relates to a probe card.

### BACKGROUND ART

In recent years, various probe cards for electrically connecting an electronic device, such as a large-scale integration (LSI) wafer, and a tester to inspect the electronic device have been developed.

Patent Document 1 describes an example of the probe card. The probe card includes an interposer located between the electronic device and the tester. A lower surface of the interposer is provided with a plurality of probes to contact a plurality of electrodes provided on an upper surface of the electronic device. A plurality of conductors such as wirings and vias connected to the plurality of probes are provided inside the interposer. The electronic device and the tester are electrically connected through the probes provided on the lower surface of the interposer and the conductors provided inside the interposer.

Patent Document 2 describes an example of the probe card. The probe card includes a flexible substrate. The electronic device and the tester are electrically connected through conductors such as wirings extending along a surface of the flexible substrate.

### RELATED DOCUMENT

### Patent Document

Patent Document 1: Japanese Unexamined Patent Publication No. 2009-276090
Patent Document 2: Japanese Unexamined Patent Publication No. 2008-82734

### SUMMARY OF THE INVENTION

### Technical Problem

A radio frequency signal (RF signal) may be transmitted between the electronic device and the tester through the probe card. A probe card including an interposer, such as the probe card described in Patent Document 1, for example, however, has a relatively long distance between the probes provided on the lower surface of the interposer and the conductors provided inside the interposer, which may lead to relatively high transmission losses of the RF signals transmitted through the probes and the conductors. A probe card including a flexible substrate, such as the probe card described in Patent Document 2, for example, may have a small number of direct current signals (DC signals), such as power supply potentials or ground potentials, or low-frequency signals (LF signals) transmitted between the electronic device and the tester.

An example of an object of the present invention is to prevent the decrease of the number of signals transmitted between an electronic device and a tester while reducing transmission losses of signals transmitted between the electronic device and the tester. Another object of the present invention will become apparent from the description of the present specification.

### Solution to Problem

One aspect of the present invention is a probe card including:
an insulating layer;
a first conductor at least partially extending along a surface of the insulating layer; and
a second conductor at least partially penetrating at least a portion of the insulating layer.

According to the above-described aspect of the present invention, the decrease of the number of signals transmitted between an electronic device and a tester can be prevented while reducing transmission losses of signals transmitted between the electronic device and the tester.

### BRIEF DESCRIPTION OF THE DRAWINGS

FIG. 1 A bottom view of a probe card according to Embodiment 1.

FIG. 2 A cross-sectional view taken along line A-A′ of FIG. 1.

FIG. 3 A cross-sectional view of a probe card according to Embodiment 2.

### DESCRIPTION OF EMBODIMENTS

Hereinafter, embodiments of the present invention will be described with reference to the drawings. In all the drawings, the same components are designated by the same reference numerals, and the description thereof will not be repeated as appropriate.

In the present specification, unless otherwise specified, ordinal numbers such as “first”, “second”, and “third” are added merely to distinguish between configurations with similar names and do not imply specific characteristics (for example, order or importance) of the configuration.

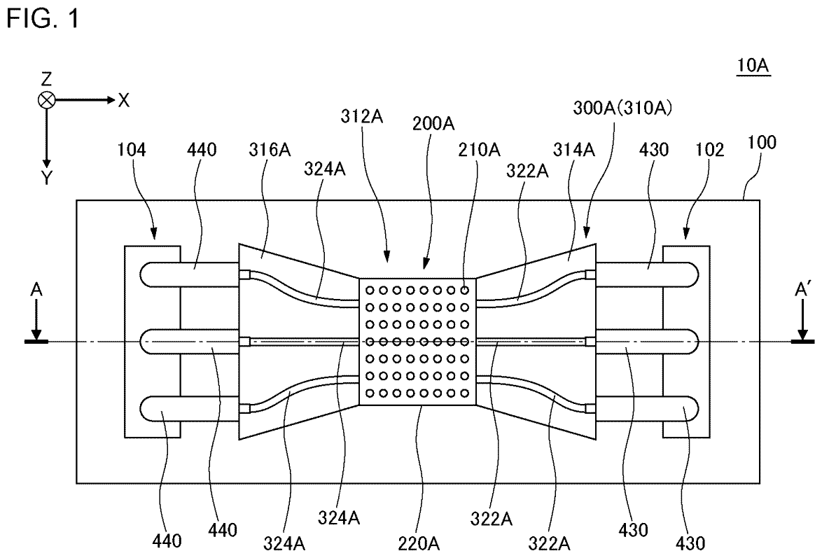

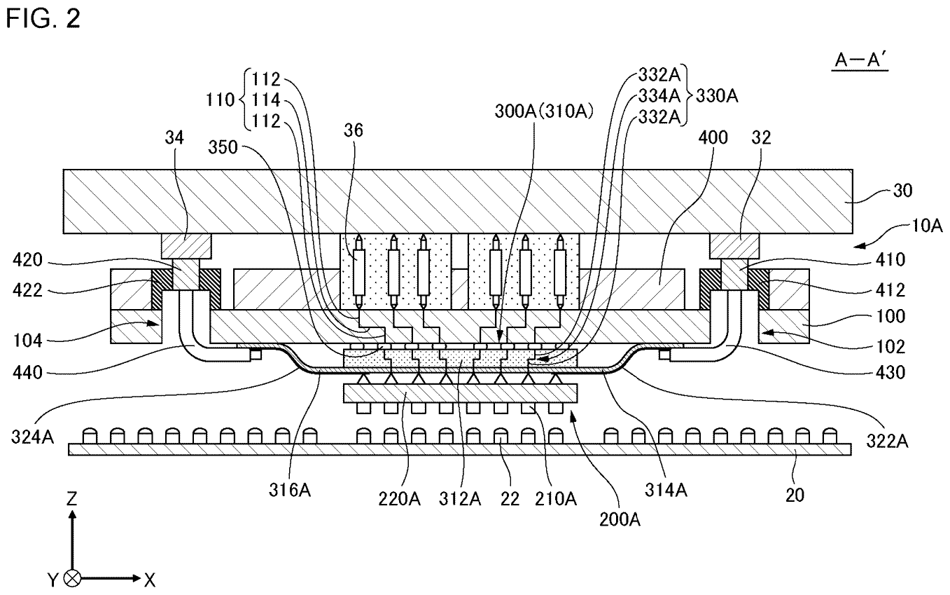

FIG. 1 is a bottom view of a probe card 10A according to Embodiment 1. FIG. 2 is a cross-sectional view taken along line A-A′ of FIG. 1. FIG. 2 shows an electronic device 20 and a tester 30 together with the probe card 10A.

In FIGS. 1 and 2, an arrow indicating a first direction X, a second direction Y, or a third direction Z indicates that a direction from a base to a tip of the arrow is a positive direction of a direction indicated by the arrow and that a direction from the tip to the base of the arrow is a negative direction of the direction indicated by the arrow. A white circle with X indicating the second direction Y or the third direction Z indicates that a direction from the foreground to the background of the paper plane is a positive direction of a direction indicated by the white circle and that a direction from the background to the foreground of the paper plane is a negative direction of the direction indicated by the white circle.

In FIGS. 1 and 2, the first direction X is a direction parallel to a horizontal direction that is orthogonal to a vertical direction. Specifically, the first direction X is a direction parallel to a longitudinal direction of a rigid substrate 100, which will be described below. The positive direction of the first direction X is a direction from a second through-hole 104, which will be described below, to a first through-hole 102, which will be described below. The negative direction of the first direction X is a direction from the second through-hole 104 to the first through-hole 102. The second direction Y is a direction parallel to a direction that is orthogonal to both the vertical direction and the first direction X. Specifically, the second direction Y is a direction parallel to a transverse direction of the rigid substrate 100. The positive direction of the second direction Y and the negative direction of the second direction Y are directions opposite to each other. The third direction Z is a direction parallel to the vertical direction. Specifically, the positive direction of the third direction Z is an upward direction from below. The negative direction of the third direction Z is a downward direction from above.

The probe card 10A is located between the electronic device 20 and the tester 30 in the third direction Z. The electronic device 20 is located below the probe card 10A. The electronic device 20 is, for example, a wafer. The tester 30 is located above the probe card 10A.

The probe card 10A includes the rigid substrate 100, a probe head 200A, a first interposer 300A, a stiffener 400, a plurality of first coaxial connectors 410, a plurality of second coaxial connectors 420, a plurality of first coaxial cables 430, and a plurality of second coaxial cables 440.

The rigid substrate 100 is, for example, a printed circuit board (PCB). The rigid substrate 100 has a thickness in a direction parallel to the third direction Z.

The rigid substrate 100 is provided with the first through-hole 102 and the second through-hole 104 arranged in the first direction X. The first through-hole 102 and the second through-hole 104 penetrate the rigid substrate 100 in the third direction Z. As shown in FIG. 1, when viewed from the negative direction of the third direction Z, the first through-hole 102 is located on a positive direction side of the first direction X with respect to the probe head 200A. When viewed from the negative direction of the third direction Z, the second through-hole 104 is located on a negative direction side of the first direction X with respect to the probe head 200A.

As shown in FIG. 2, the rigid substrate 100 includes a plurality of first connection conductors 110. Each first connection conductor 110 includes a plurality of first vias 112 extending in the third direction Z and a first wiring 114 extending in a direction orthogonal to the third direction Z. A position of an upper end of the first connection conductor 110 and a position of a lower end of the first connection conductor 110 are offset through the first wiring 114 in a direction perpendicular to the third direction Z. In the example shown in FIG. 2, the first wiring 114 extends in a direction away from the center in the first direction X of the rigid substrate 100 from the first via 112 including the lower end of each first connection conductor 110 toward the first via 112 including the upper end of each first connection conductor 110. As a result, the pitch of the upper ends of the plurality of first connection conductors 110 in the first direction X is larger than the pitch of the lower ends of the plurality of first connection conductors 110 in the first direction X. The shape of the first connection conductor 110 is not limited to the example shown in FIG. 2. For example, the first connection conductor 110 may include the first via 112 extending in a direction parallel to the third direction Z without including the first wiring 114 extending in a direction orthogonal to the third direction Z. In this example, the position of the upper end of the first connection conductor 110 and the position of the lower end of the first connection conductor 110 are aligned in the third direction Z.

As shown in FIG. 2, the probe head 200A is located below the rigid substrate 100 through the first interposer 300A. As shown in FIG. 1, when viewed from the negative direction of the third direction Z, the probe head 200A is located between the first through-hole 102 and the second through-hole 104 in the first direction X.

The probe head 200A includes a plurality of probes 210A and an insulating support 220A.

As shown in FIG. 1, the plurality of probes 210A are arranged in a matrix when viewed from the negative direction of the third direction Z. In the example shown in FIG. 1, when viewed from the negative direction of the third direction Z, the plurality of probes 210A are arranged in a matrix with eight columns in the first direction X and seven rows in the second direction Y. A layout of the plurality of probes 210A is not limited to the example shown in FIG. 1.

The insulating support 220A supports the plurality of probes 210A. As shown in FIG. 2, the insulating support 220A has a thickness in a direction parallel to the third direction Z. An upper surface of the insulating support 220A faces a portion of a lower surface of the rigid substrate 100 located between the first through-hole 102 and the second through-hole 104 in the first direction X through the first interposer 300A. A lower surface of the insulating support 220A faces an upper surface of the electronic device 20.

Each probe 210A is provided to penetrate the insulating support 220A in the third direction Z. An upper end of each probe 210A protruding upward from the upper surface of the insulating support 220A and a lower end of each probe 210A protruding downward from the lower surface of the insulating support 220A are biased toward directions away from each other in the third direction Z by, for example, an elastic member such as a spring provided between the upper end and the lower end of each probe 210A.

In the present embodiment, the plurality of probes 210A can be individually inserted and removed with respect to the insulating support 220A. Accordingly, when fault such as wear requires the replacement of some of the probes 210A among the plurality of probes 210A, only faulted probe 210A can be replaced without need to replace the entire probe head 200A. In a case such as when using a flexible substrate such as a flexible printed circuit (FPC) provided with a plurality of probes, on the other hand, there is a case where fault on some probes requires replacement of all of the plurality of probes because the plurality of probes cannot be individually replaced. According to the present embodiment, the maintaining cost of the probe card 10A can be reduced as compared with such a case. Depending on a structure of the probe head 200A, the plurality of probes 210A may not be individually inserted and removed with respect to the insulating support 220A.

The first interposer 300A includes a first insulating layer 310A, a plurality of first transmission conductors 322A, a plurality of second transmission conductors 324A, and a plurality of third transmission conductors 330A.

The first insulating layer 310A includes a first base region 312A, a first extension region 314A, and a second extension region 316A. The first insulating layer 310A is, for example, an insulating laminate. This insulating laminate is, for example, an organic multilayer substrate.

The first base region 312A has a thickness in a direction parallel to the third direction Z. The first base region 312A includes a plurality of insulating layers stacked in the third direction Z. An upper surface of the first base region 312A faces a portion of the lower surface of the rigid substrate 100 located between the first through-hole 102 and the second through-hole 104 in the first direction X through a plurality of bumps 350. A lower surface of the first base region 312A faces the upper surface of the insulating support 220A.

The first extension region 314A is drawn from a lowermost insulating layer of the first base region 312A toward the outside in the positive direction of the first direction X. The first extension region 314A is formed, for example, by processing the insulating laminate such as an organic multilayer substrate such that a portion to be the first extension region 314A is thinner in the third direction Z than a portion to be the first base region 312A. The thickness of the first extension region 314A in the third direction Z thinner than the thickness of the first base region 312A in the third direction z can make the flexibility of the first extension region 314A higher than the flexibility of the first base region 312A. The shape of the first extension region 314A can be therefore deformed into an appropriate shape. In the example shown in FIG. 2, the first extension region 314A is bent toward the lower surface of the rigid substrate 100 from the first base region 312A toward the first through-hole 102.

The second extension region 316A is drawn from the lowermost insulating layer of the first base region 312A toward the outside in the negative direction of the first direction X. The second extension region 316A is formed, for example, by processing the insulating laminate such as an organic multilayer substrate such that a portion to be the second extension region 316A is thinner in the third direction Z than the portion to be the first base region 312A. Having the thickness of the second extension region 316A in the third direction Z be thinner than the thickness of the first base region 312A in the third direction Z can make the flexibility of the second extension region 316A higher than the flexibility of the first base region 312A. The shape of the second extension region 316A can be therefore deformed into an appropriate shape. In the example shown in FIG. 2, the second extension region 316A is bent toward the lower surface of the rigid substrate 100 from the first base region 312A toward the second through-hole 104.

When the electronic device 20 and the tester 30 are electrically connected through the probe card 10A, the plurality of first transmission conductors 322A and the plurality of second transmission conductors 324A transmit signals of a first frequency. In this case, the plurality of third transmission conductors 330A transmit at least one of direct current signals (DC signals) and signals of a second frequency that is a frequency lower than the first frequency. The signal of the first frequency transmitted by the first transmission conductor 322A or the second transmission conductor 324A is, for example, a radio frequency signal (RF signal). The DC signal transmitted by the third transmission conductor 330A is, for example, a power supply potential or a ground potential. The signal of the second frequency transmitted by the third transmission conductor 330A is, for example, a low frequency signal (LF signal). Hereinafter, the plurality of first transmission conductors 322A and the plurality of second transmission conductors 324A are descried as transmitting the RF signals. In addition, hereinafter, the plurality of third transmission conductors 330A are described as transmitting at least one of the DC signals and the LF signals.

With reference to FIG. 1, the details of the layout of the plurality of first transmission conductors 322A and the plurality of second transmission conductors 324A when viewed from the negative direction of the third direction Z will be described. The layout of the plurality of first transmission conductors 322A and the plurality of second transmission conductors 324A when viewed from the negative direction of the third direction Z is not limited to the example shown in FIG. 1.

The first extension region 314A is provided with three first transmission conductors 322A arranged in the second direction Y. Each first transmission conductor 322A extends from a region overlapping the probe head 200A in the third direction Z toward the positive direction of the first direction X. An end portion of each first transmission conductor 322A on the negative direction side of the first direction X is connected to any one of the seven probes 210A located in the column at the most end in the positive direction of the first direction X among the plurality of probes 210A arranged in a matrix in the first direction X and the second direction Y. The above end portion of the first transmission conductor 322A located at the center of the second direction Y among the three first transmission conductors 322A is connected to the probe 210A located in the row at the center of the second direction Y within the above column. The above end portion of the first transmission conductor 322A located on a positive direction side of the second direction Y with respect to the first transmission conductor 322A located at the center of the second direction Y is connected to the probe 210A offset by two rows from the row at the center of the second direction Y toward the positive direction of the second direction Y within the above column. The above end portion of the first transmission conductor 322A located on a negative direction side of the second direction Y with respect to the first transmission conductor 322A located at the center of the second direction Y is connected to the probe 210A offset by two rows from the row at the center of the second direction Y toward the negative direction of the second direction Y within the above column.

The second extension region 316A is provided with three second transmission conductors 324A disposed symmetrically with the three first transmission conductors 322A with respect to the center of the first base region 312A in the first direction X. Each second transmission conductor 324A extends from a region overlapping the probe head 200A in the third direction Z toward the negative direction of the first direction X. An end portion of each second transmission conductor 324A on the positive direction side of the first direction X is connected any one of the seven probes 210A located in the column at the most end in the negative direction of the first direction X among the plurality of probes 210A arranged in a matrix in the first direction X and the second direction Y. The above end portion of the second transmission conductor 324A located at the center of the second direction Y among the three second transmission conductors 324A is connected to the probe 210A located in the row at the center of the second direction Y within the above column. The above end portion of the second transmission conductor 324A located on the positive direction side of the second direction Y with respect to the second transmission conductor 324A located at the center of the second direction Y is connected to the probe 210A offset by two rows from the row at the center of the second direction Y toward the positive direction of the second direction Y within the above column. The above end portion of the second transmission conductor 324A located on a negative direction side of the second direction Y with respect to the second transmission conductor 324A located at the center of the second direction Y is connected to the probe 210A offset by two rows from the row at the center of the second direction Y toward the negative direction of the second direction Y within the above column.

With reference to FIG. 2, the details of the first transmission conductor 322A and the second transmission conductor 324A will be described.

As shown in FIG. 2, at least a portion of the first transmission conductor 322A extends along a surface of the first extension region 314A. Accordingly, the deformation of the shape of the first extension region 314A into an appropriate shape enables the first transmission conductor 322A to be drawn from the first base region 312A toward an appropriate position along the first extension region 314A. In the example shown in FIG. 2, at least a portion of the first transmission conductor 322A is provided along a lower surface of the first extension region 314A. The example shown in FIG. 2 is compared with a case where the first transmission conductor 322A is provided along an upper surface of the first extension region 314A. A distance in the third direction Z between the end portion of the first transmission conductor 322A on the negative direction side of the first direction X and the upper end of the probe 210A connected to the end portion of the first transmission conductor 322A in the example shown in FIG. 2 can be shorter than that in the above case. In the example shown in FIG. 2, therefore, the transmission losses of the RF signals transmitted between the above end portion of the first transmission conductor 322A and the upper end of the probe 210A connected to the end portion of the first transmission conductor 322A can be reduced as compared with the above case. In another example different from the present embodiment, the first transmission conductor 322A may be provided along the upper surface of the first extension region 314A.

As shown in FIG. 2, at least a portion of the second transmission conductor 324A extends along a surface of the second extension region 316A. Accordingly, the deformation of the shape of the second extension region 316A into an appropriate shape enables the second transmission conductor 324A to be drawn from the first base region 312A toward an appropriate position along the second extension region 316A. In the example shown in FIG. 2, at least a portion of the second transmission conductor 324A is provided along a lower surface of the second extension region 316A. The example shown in FIG. 2 is compared with a case where the second transmission conductor 324A is provided along an upper surface of the second extension region 316A. A distance in the third direction Z between the end portion of the second transmission conductor 324A on the positive direction side of the first direction X and the upper end of the probe 210A connected to the end portion of the second transmission conductor 324A in the example shown in FIG. 2 can shorter than that in the above case. In the example shown in FIG. 2, therefore, the transmission losses of the RF signals transmitted between the above end portion of the second transmission conductor 324A and the upper end of the probe 210A connected to the end portion of the second transmission conductor 324A can be reduced as compared with the above case. In another example different from the present embodiment, the second transmission conductor 324A may be provided along the upper surface of the second extension region 316A.

As shown in FIG. 2, at least a portion of each third transmission conductor 330A penetrates at least a portion of the first base region 312A in the third direction Z. Specifically, each third transmission conductor 330A includes a plurality of second vias 332A extending in a direction parallel to the third direction Z and a second wiring 334A extending in a direction orthogonal to the third direction Z. A position of an upper end of the third transmission conductor 330A and a position of a lower end of the third transmission conductor 330A are offset through the second wiring 334A in a direction perpendicular to the third direction Z. In the example shown in FIG. 2, the second wiring 334A extends in a direction away from the center in the first direction X of the first base region 312A from the second via 332A including the lower end of each third transmission conductor 330A toward the second via 332A including the upper end of each third transmission conductor 330A. As a result, the pitch of the upper ends of the plurality of third transmission conductors 330A in the first direction X is larger than the pitch of the lower ends of the plurality of third transmission conductors 330A in the first direction X. The shape of the third transmission conductor 330A is not limited to the example shown in FIG. 2.

The plurality of first connection conductors 110 are electrically connected to the plurality of probes 210A different from the probe 210A connected to the first transmission conductor 322A or the second transmission conductor 324A through the plurality of bumps 350 and the plurality of third transmission conductors 330A. In the example shown in FIG. 2, the six first connection conductors 110 are electrically connected to the six probes 210A at the center of the first direction X among the eight probes 210A through the six bumps 350 at the center of the first direction X among the eight bumps 350 and the six third transmission conductors 330A.

Specifically, the upper end of each third transmission conductor 330A is electrically connected to the lower end of each first connection conductor 110 through each bump 350. The lower end of each third transmission conductor 330A is electrically connected to the upper end of each probe 210A. The first interposer 300A accordingly makes the pitch of the lower ends of the plurality of first connection conductors 110 in the direction perpendicular to the third direction Z larger than the pitch of the upper ends of the plurality of probes 210A in the direction perpendicular to the third direction Z.

A structure of the first interposer 300A is not limited to the structure according to the present embodiment.

For example, in the present embodiment, the first extension region 314A is drawn from the lowermost insulating layer of the first base region 312A. The present embodiment is compared with a case where the first extension region 314A is drawn from the insulating layer above the lowermost insulating layer of the first base region 312A. The distance in the third direction Z between the end portion of the first transmission conductor 322A on the negative direction side of the first direction X and the upper end of the probe 210A connected to the end portion of the first transmission conductor 322A in the present embodiment can be shorter than that in the above case. In the present embodiment, therefore, the transmission losses of the RF signals transmitted between the end portion of the first transmission conductor 322A on the negative direction side of the first direction X and the upper end of the probe 210A connected to the end portion of the first transmission conductor 322A can be reduced as compared with the above case. However, the first extension region 314A may be drawn from the insulating layer above the lowermost insulating layer of the first base region 312A. The same applies to the second extension region 316A.

The first interposer 300A may include a flexible substrate such as FPC attached to the lower surface of the first base region 312A instead of the first extension region 314A and the second extension region 316A. In this case, the first transmission conductor 322A and the second transmission conductor 324A can be provided on the flexible substrate attached to the lower surface of the first base region 312A. The stiffener 400 is located above the upper surface of the rigid substrate 100. For example, the stiffener 400 is fixed to the upper surface of the rigid substrate 100 with a fixing member (not shown) such as a screw. The mechanical strength of the rigid substrate 100 can be improved when the stiffener 400 is provided as compared with when the stiffener 400 is not provided.

In the present embodiment, three first coaxial connectors 410 are connected to upper ends of the three first coaxial cables 430 connected to the three first transmission conductors 322A shown in FIG. 1. As shown in FIG. 2, the first coaxial connector 410 is held above the first through-hole 102 by a first holder 412 fixed to a hole provided in a region of the stiffener 400 overlapping the first through-hole 102.

In the present embodiment, three second coaxial connectors 420 are connected to upper ends of the three second coaxial cables 440 connected to the three second transmission conductors 324A shown in FIG. 1. As shown in FIG. 2, the second coaxial connector 420 is held above the second through-hole 104 by a second holder 422 fixed to a hole provided in a region of the stiffener 400 overlapping the second through-hole 104.

The upper end of the first coaxial cable 430 is connected to the lower end of the first coaxial connector 410. A portion of the first coaxial cable 430 is drawn from the first coaxial connector 410 through the first through-hole 102 to below the lower surface of the rigid substrate 100. The portion of the first coaxial cable 430 drawn below the lower surface of the rigid substrate 100 is bent toward a side where the first extension region 314A is located. An end portion of the portion of the first coaxial cable 430 bent toward the side where the first extension region 314A is located is connected to the end portion of the first transmission conductor 322A on the positive direction side of the first direction X.

The upper end of the second coaxial cable 440 is connected to the lower end of the second coaxial connector 420. A portion of the second coaxial cable 440 is drawn from the second coaxial connector 420 through the second through-hole 104 to below the lower surface of the rigid substrate 100. The portion of the second coaxial cable 440 drawn below the lower surface of the rigid substrate 100 is bent toward a side where the second extension region 316A is located. An end portion of the portion of the second coaxial cable 440 bent toward the side where the second extension region 316A is located is connected to the end portion of the second transmission conductor 324A on the negative direction side of the first direction X.

Next, an example of a method of electrically connecting the electronic device 20 and the tester 30 through the probe card 10A will be described.

When the electronic device 20 and the tester 30 are electrically connected through the probe card 10A, each of the lower ends of the plurality of probes 210A contacts with each of upper ends of a plurality of electrodes 22 provided on the upper surface of the electronic device 20. In the example shown in FIG. 2, each of the lower ends of the eight probes 210A contacts with each of upper ends of the eight electrodes 22 located below the eight probes 210A. An upper end of the first coaxial connector 410 is connected to a lower end of a first RF connector 32 provided on a lower surface of the tester 30. Similarly, an upper end of the second coaxial connector 420 is connected to a lower end of a second RF connector 34 provided on the lower surface of the tester 30. Furthermore, each of the upper ends of the plurality of first connection conductors 110 is connected to each of the lower ends of a plurality of direct current/low frequency (DC/LF) connectors 36 provided on the lower surface of the tester 30. In the example shown in FIG. 2, each DC/LF connector 36 is a probe. A structure of the DC/LF connector 36 is not limited to the example shown in FIG. 2.

When the electronic device 20 and the tester 30 are electrically connected through the probe card 10A, the first RF connector 32 is electrically connected, through the first coaxial connector 410, the first coaxial cable 430, the first transmission conductor 322A, and the probe 210A electrically connected to the first transmission conductor 322A, to the electrode 22 located below the probe 210A electrically connected to the first transmission conductor 322A. In the example shown in FIG. 2, the first RF connector 32 is electrically connected, through the first coaxial connector 410, the first coaxial cable 430, the first transmission conductor 322A, and the probe 210A located at the most end in the positive direction of the first direction X among the eight probes 210A, to the electrode 22 located below the probe 210A located at the most end in the positive direction of the first direction X among the eight probes 210A.

When the electronic device 20 and the tester 30 are electrically connected through the probe card 10A, the second RF connector 34 is electrically connected, through the second coaxial connector 420, the second coaxial cable 440, the second transmission conductor 324A, and the probe 210A electrically connected to the second transmission conductor 324A, to the electrode 22 located below the probe 210A electrically connected to the second transmission conductor 324A. In the example shown in FIG. 2, the second RF connector 34 is electrically connected, through the second coaxial connector 420, the second coaxial cable 440, the second transmission conductor 324A, and the probe 210A located at the most end in the negative direction of the first direction X among the eight probes 210A, to the electrode 22 located below the probe 210A located at the most end in the negative direction of the first direction X among the eight probes 210A.

When the electronic device 20 and the tester 30 are electrically connected through the probe card 10A, the DC/LF connector 36 is electrically connected, through the first connection conductor 110, the bump 350, the third transmission conductor 330A, and the probe 210A electrically connected to the third transmission conductor 330A, to the electrode 22 located below the probe 210A electrically connected to the third transmission conductor 330A. In the example shown in FIG. 2, the six DC/LF connectors 36 are electrically connected, through the six first connection conductors 110, the six bumps 350 at the center of the first direction X among the eight bumps 350, the six third transmission conductors 330A, and the six probes 210A at the center of the first direction X among the eight probes 210A, to the six electrodes 22 located below the six probes 210A at the center of the first direction X among the eight probes 210A.

In the present embodiment, as described above, at least a portion of the first transmission conductor 322A extends along the surface of the first extension region 314A. The present embodiment is compared with a case where the first transmission conductor 322A penetrates the first base region 312A. The length of the first transmission conductor 322A in the present embodiment can be shorter than that in the above case. In the present embodiment, therefore, the transmission losses of the RF signals transmitted through the first transmission conductor 322A between the first RF connector 32 and the electrode 22 electrically connected to the first RF connector 32 can be reduced as compared with the above case. Similarly, in the present embodiment, as described above, at least a portion of the second transmission conductor 324A extends along the surface of the second extension region 316A. The present embodiment is compared with a case where the second transmission conductor 324A penetrates the first base region 312A. The length of the second transmission conductor 324A in the present embodiment can be shorter than that in the above case. In the present embodiment, therefore, the transmission losses of the RF signals transmitted through the second transmission conductor 324A between the second RF connector 34 and the electrode 22 electrically connected to the second RF connector 34 can be reduced as compared with the above case.

In the present embodiment, as described above, at least a portion of the third transmission conductor 330A penetrates at least a portion of the first base region 312A. The present embodiment is compared with a case where the third transmission conductor 330A extends along the surface of the first extension region 314A or the second extension region 316A. In the present embodiment, the decrease of the number of DC signals and LF signals transmitted through the third transmission conductor 330A between the DC/LF connector 36 and the electrode 22 electrically connected to the DC/LF connector 36 can be prevented as compared with the above case.

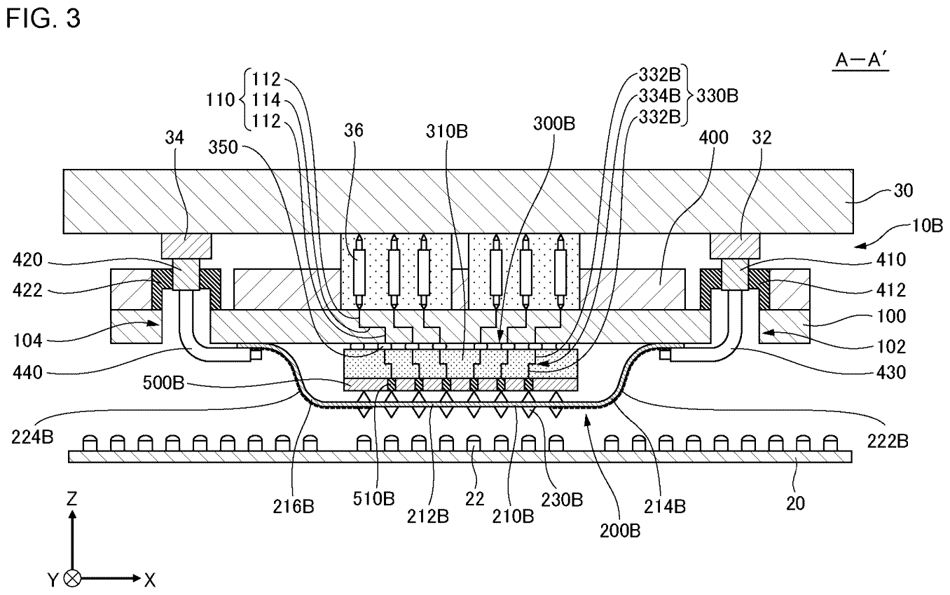

FIG. 3 is a cross-sectional view of a probe card 10B according to Embodiment 2. The probe card 10B according to Embodiment 2 is the same as the probe card 10A according to Embodiment 1 except for the following points.

The probe card 10B includes a flexible substrate 200B, a second interposer 300B, and an anisotropic conductive rubber 500B.

The flexible substrate 200B includes a second insulating layer 210B, a plurality of fourth transmission conductors 222B, a plurality of fifth transmission conductors 224B, and a plurality of sixth transmission conductors 230B.

The second insulating layer 210B includes a second base region 212B, a third extension region 214B, and a fourth extension region 216B. In one example, a layout of the second insulating layer 210B according to Embodiment 2 when viewed from the negative direction of the third direction Z is the same as the layout of the first insulating layer 310A according to the embodiment when viewed from the negative direction of the third direction Z. In this example, the second base region 212B is located between the first through-hole 102 and the second through-hole 104 in the first direction X. When viewed from the negative direction of the third direction z, the third extension region 214B extends from the second base region 212B toward the first through-hole 102. The flexibility of the second insulating layer 210B enables the third extension region 214B to deform into an appropriate shape. In the example shown in FIG. 3, the third extension region 214B is bent toward the lower surface of the rigid substrate 100 from the second base region 212B toward the first through-hole 102. When viewed from the negative direction of the third direction Z, the fourth extension region 216B extends from the second base region 212B toward the second through-hole 104. The flexibility of the second insulating layer 210B enables the fourth extension region 216B to deform into an appropriate shape. In the example shown in FIG. 3, the fourth extension region 216B is bent toward the lower surface of the rigid substrate 100 from the second base region 212B toward the second through-hole 104.

When the electronic device 20 and the tester 30 are electrically connected through the probe card 10B, a fourth transmission conductor 222B and a fifth transmission conductor 224B according to Embodiment 2 transmit the RF signals similarly to the first transmission conductor 322A and the second transmission conductor 324A according to Embodiment 1. When the electronic device 20 and the tester 30 are electrically connected through the probe card 10B, a sixth transmission conductor 230B according to Embodiment 2 transmits at least one of the DC signal and the LF signal similarly to the third transmission conductor 330A according to Embodiment 1.

A layout of the plurality of fourth transmission conductors 222B and the plurality of fifth transmission conductors 224B according to Embodiment 2 when viewed from the negative direction of the third direction Z may be, for example, similar to the layout of the first transmission conductor 322A and the plurality of second transmission conductors 324A according to Embodiment 1 when viewed from the negative direction of the third direction Z.

As shown in FIG. 3, at least a portion of the fourth transmission conductor 222B extends along a surface of the third extension region 214B. Accordingly, the deformation of the shape of the third extension region 214B into an appropriate shape enables the fourth transmission conductor 222B to be drawn from the second base region 212B toward an appropriate position along the third extension region 214B. In the example shown in FIG. 3, at least a portion of the fourth transmission conductor 222B is provided along a lower surface of the third extension region 214B. In another example different from the present embodiment, the fourth transmission conductor 222B may be provided along an upper surface of the third extension region 214B.

As shown in FIG. 3, at least a portion of the fifth transmission conductor 224B extends along a surface of the fourth extension region 216B. Accordingly, the deformation of the shape of the fourth extension region 216B into an appropriate shape enables the fifth transmission conductor 224B to be drawn from the second base region 212B toward an appropriate position along the fourth extension region 216B. In the example shown in FIG. 3, at least a portion of the fifth transmission conductor 224B is provided along a lower surface of the fourth extension region 216B. In another example different from the present embodiment, the fifth transmission conductor 224B may be provided along an upper surface of the fourth extension region 216B.

As shown in FIG. 3, at least a portion of each sixth transmission conductor 230B penetrates at least a portion of the second base region 212B in the third direction Z. Specifically, an upper end of the sixth transmission conductor 230B protruding upward from an upper surface of the second base region 212B and a lower end of the sixth transmission conductor 230B protruding downward from a lower surface of the second base region 212B are electrically connected by a portion of the sixth transmission conductor 230B embedded inside the second base region 212B. The upper end of the sixth transmission conductor 230B protruding upward from the upper surface of the second base region 212B and the lower end of the sixth transmission conductor 230B protruding downward from the lower surface of the second base region 212B may be biased toward directions away from each other in the third direction Z by elasticity of the second base region 212B.

In one example, similarly to the plurality of probes 210A according to Embodiment 1, when viewed from the negative direction of the third direction Z, the plurality of sixth transmission conductors 230B according to Embodiment 2 may be arranged in a matrix in the first direction X and the second direction Y. In this example, similarly to Embodiment 1, the end portion of the fourth transmission conductor 222B on the negative direction side of the first direction X is connected to any one of the sixth transmission conductors 230B located in the column at the most end in the positive direction of the first direction X among the plurality of sixth transmission conductors 230B arranged in a matrix in the first direction X and the second direction Y. Similarly to Embodiment 1, the end portion of the fifth transmission conductor 224B on the positive direction side of the first direction X is connected to any one of the sixth transmission conductors 230B located in the column at the most end in the negative direction of the first direction X among the plurality of sixth transmission conductors 230B arranged in a matrix in the first direction X and the second direction Y.

The second interposer 300B has a third insulating layer 310B and a plurality of second connection conductors 330B.

The third insulating layer 310B has a thickness in a direction parallel to the third direction Z. The third insulating layer 310B includes a plurality of insulating layers stacked in the third direction Z. An upper surface of the third insulating layer 310B faces a portion of the lower surface of the rigid substrate 100 located between the first through-hole 102 and the second through-hole 104 in the first direction X through the plurality of bumps 350. A lower surface of the third insulating layer 310B faces the upper surface of the second base region 212B through the anisotropic conductive rubber 500B.

Similarly to the third transmission conductor 330A according to Embodiment 1, as shown in FIG. 3, each second connection conductor 330B includes a plurality of second vias 332B extending in a direction parallel to the third direction Z and a second wiring 334B extending in a direction orthogonal to the third direction Z. The shape of the second connection conductor 330B is not limited to the example shown in FIG. 3.

The plurality of first connection conductors 110 are electrically connected to the plurality of sixth transmission conductors 230B different from the sixth transmission conductor 230B connected to the fourth transmission conductor 222B or the fifth transmission conductor 224B through the plurality of bumps 350, the plurality of second connection conductors 330B, and a plurality of connection portions 510B, which will be described below. In the example shown in FIG. 3, the six first connection conductors 110 are electrically connected to the six sixth transmission conductors 230B at the center of the first direction X among the eight sixth transmission conductors 230B through the six bumps 350 at the center of the first direction X among the eight bumps 350, the six second connection conductors 330B, and the six connection portions 510B. Specifically, the upper end of each second connection conductor 330B is electrically connected to the lower end of each first connection conductor 110 through each bump 350. The lower end of each second connection conductor 330B is electrically connected to the upper end of each sixth transmission conductor 230B through each connection portion 510B. The second interposer 300B accordingly makes the pitch of the lower ends of the first connection conductors 110 in the direction perpendicular to the third direction Z larger than the pitch of the upper ends of the plurality of sixth transmission conductors 230B in the direction perpendicular to the third direction Z.

The anisotropic conductive rubber 500B has a thickness in a direction parallel to the third direction Z. The upper end of the sixth transmission conductor 230B is in contact with a lower surface of the anisotropic conductive rubber 500B. The lower end of the sixth transmission conductor 230B is therefore biased downward by elasticity of the anisotropic conductive rubber 500B. That is, the elasticity of the anisotropic conductive rubber 500B according to Embodiment 2 has the same function as the elastic member such as a spring provided in the probe 210A according to Embodiment 1.

A compressive force applied in the third direction Z to the connection portion 510B of the anisotropic conductive rubber 500B located between the lower end of the second connection conductor 330B and the upper end of the sixth transmission conductor 230B in the third direction Z makes the conductivity of the connection portion 510B higher than the conductivity around the connection portion 510B within the anisotropic conductive rubber 500B. In one example, the anisotropic conductive rubber 500B contains rubber and a plurality of conductive particles dispersed inside the rubber. In this example, the connection portion 510B compressed in the third direction Z makes the plurality of conductive particles inside the connection portion in contact with each other and makes the conductivity at the connection portion 510B higher than the conductivity around the connection portion 510B. Alternatively, in another example, the anisotropic conductive rubber 500B may contain rubber and a metal wire embedded inside the rubber. The metal wire is parallel to the third direction Z or is inclined obliquely with respect to the third direction Z. In this example, the connection portion 510B compressed in the third direction Z can make the lower end of the second connection conductor 330B and the upper end of the sixth transmission conductor 230B electrically connected through each connection portion 510B with the connection portions 510B adjacent to each other in the direction perpendicular to the third direction Z electrically insulated.

When the electronic device 20 and the tester 30 are electrically connected through the probe card 10B, the first RF connector 32 is electrically connected, through the first coaxial connector 410, the first coaxial cable 430, the fourth transmission conductor 222B, and the sixth transmission conductor 230B electrically connected to the fourth transmission conductor 222B, to the electrode 22 located below the sixth transmission conductor 230B electrically connected to the fourth transmission conductor 222B. In the example shown in FIG. 3, the first RF connector 32 is electrically connected, through the first coaxial connector 410, the first coaxial cable 430, the fourth transmission conductor 222B, and the sixth transmission conductor 230B located at the most end in the positive direction of the first direction X among the eight sixth transmission conductors 230B, to the electrode 22 located below the sixth transmission conductor 230B located at the most end in the positive direction of the first direction X among the eight sixth transmission conductors 230B.

When the electronic device 20 and the tester 30 are electrically connected through the probe card 10B, the second RF connector 34 is electrically connected, through the second coaxial connector 420, the second coaxial cable 440, the fifth transmission conductor 224B, and the sixth transmission conductor 230B electrically connected to the fifth transmission conductor 224B, to the electrode 22 located below the sixth transmission conductor 230B electrically connected to the fifth transmission conductor 224B. In the example shown in FIG. 3, the second RF connector 34 is electrically connected, through the second coaxial connector 420, the second coaxial cable 440, the fifth transmission conductor 224B, and the sixth transmission conductor 230B located at the most end in the negative direction of the first direction X among the eight sixth transmission conductors 230B, to the electrode 22 located below the sixth transmission conductor 230B located at the most end in the negative direction of the first direction X among the eight sixth transmission conductors 230B.

When the electronic device 20 and the tester 30 are electrically connected through the probe card 10B, the DC/LF connector 36 is electrically connected, through the first connection conductor 110, the bump 350, the second connection conductor 330B, the connection portion 510B, and the sixth transmission conductor 230B electrically connected to the second connection conductor 330B through the connection portion 510B, to the electrode 22 located below the sixth transmission conductor 230B electrically connected to the second connection conductor 330B through the connection portion 510B. In the example shown in FIG. 3, the six DC/LF connectors 36 are electrically connected, through the six first connection conductors 110, the six bumps 350 at the center of the first direction X among the eight bumps 350, the six second connection conductors 330B, the six connection portions 510B, and the six sixth transmission conductors 230B at the center of the first direction X among the eight sixth transmission conductors 230B, to the six electrodes 22 located below the six sixth transmission conductors 230B at the center of the first direction X among the eight sixth transmission conductors 230B.

In the present embodiment, as described above, at least a portion of the fourth transmission conductor 222B extends along the surface of the third extension region 214B. The present embodiment is compared with a case where the fourth transmission conductor 222B penetrates the second base region 212B and is drawn from the lower surface toward the upper surface of the third insulating layer 310B. The length of the fourth transmission conductor 222B in the present embodiment can be shorter than that in the above case. In the present embodiment, therefore, the transmission losses of the RF signals transmitted through the fourth transmission conductor 222B between the first RF connector 32 and the electrode 22 electrically connected to the first RF connector 32 can be reduced as compared with the above case. Similarly, in the present embodiment, as described above, at least a portion of the fifth transmission conductor 224B extends along the surface of the fourth extension region 216B. The present embodiment is compared with a case where the fifth transmission conductor 224B penetrates the second base region 212B and is drawn from the lower surface toward the upper surface of the third insulating layer 310B. The length of the fifth transmission conductor 224B in the present embodiment can be shorter than that in the above case. In the present embodiment, therefore, the transmission losses of the RF signals transmitted through the fifth transmission conductor 224B between the second RF connector 34 and the electrode 22 electrically connected to the second RF connector 34 can be reduced as compared with the above case.

In the present embodiment, as described above, at least a portion of the sixth transmission conductor 230B electrically connected to the DC/LF connector 36 penetrates at least a portion of the second base region 212B. The present embodiment is compared with a case where the sixth transmission conductor 230B electrically connected to the DC/LF connector 36 extends along the surface of the third extension region 214B or the fourth extension region 216B. In the present embodiment, the decrease of the number of DC signals and LF signals transmitted through the sixth transmission conductor 230B between the DC/LF connector 36 and the electrode 22 electrically connected to the DC/LF connector 36 can be prevented as compared with the above case.

According to the present embodiment, the lower end of the sixth transmission conductor 230B can be brought into direct contact with the upper end of the electrode 22 without through the probe head. The distance in the third direction Z between the lower end of the sixth transmission conductor 230B and the upper end of the electrode 22 can be therefore shorter than that in a case where a pogo-pin type probe head is provided between the lower end of the sixth transmission conductor 230B and the upper end of the electrode 22. Accordingly, the transmission losses of the RF signals transmitted between the lower end of the sixth transmission conductor 230B and the upper end of the electrode 22 can be reduced as compared with a case where a pogo-pin type probe head is provided between the lower end of the sixth transmission conductor 230B and the upper end of the electrode 22.

A structure of the probe card 10B is not limited to the structure according to the present embodiment.

For example, the probe card 10B may not include the anisotropic conductive rubber 500B. In this case, the upper end of the sixth transmission conductor 230B may be in direct contact with the lower surface of the second interposer 300B without through the anisotropic conductive rubber 500B.

The probe card 10B may not include the second interposer 300B. There is no need to provide the second interposer 300B when, for example, there is no need for the second interposer 300B to make the pitch of the upper ends of the plurality of second connection conductors 330B larger than the pitch of the lower ends of the plurality of second connection conductors 330B. In this case, the upper end of the sixth transmission conductor 230B may be in direct contact with the lower surface of the rigid substrate 100 without through the anisotropic conductive rubber 500B, the second interposer 300B, and the plurality of bumps 350.

Although the embodiments of the present invention have been described above with reference to the drawings, these are examples of the present invention, and various configurations other than the above description may also be employed.

For example, in Embodiment 1, the first transmission conductor 322A and the second transmission conductor 324A may transmit at least one of the DC signal and the LF signal. In this case, the transmission losses of the DC signals and the LF signals transmitted through the first transmission conductor 322A or the second transmission conductor 324A between the electronic device 20 and the tester 30 can be reduced as compared with a case where the first transmission conductor 322A and the second transmission conductor 324A penetrate the first base region 312A. The third transmission conductor 330A may transmit the RF signal. In this case, the decrease of the number of RF signals transmitted through the third transmission conductor 330A between the electronic device 20 and the tester 30 can be prevented as compared with a case where the third transmission conductor 330A extends along the surface of the first extension region 314A or the second extension region 316A. Also, in Embodiment 2, similarly, the fourth transmission conductor 222B and the fifth transmission conductor 224B may transmit at least one of the DC signal and the LF signal. In this case, the transmission losses of the DC signals and the LF signals transmitted through the fourth transmission conductor 222B or the fifth transmission conductor 224B between the electronic device 20 and the tester 30 can be reduced as compared with a case where the fourth transmission conductor 222B and the fifth transmission conductor 224B penetrate the second base region 212B. The sixth transmission conductor 230B may transmit the RF signal. In this case, the decrease of the number of RF signals transmitted through the sixth transmission conductor 230B between the electronic device 20 and the tester 30 can be prevented as compared with a case where the sixth transmission conductor 230B extends along the surface of the third extension region 214B or the fourth extension region 216B.

According to the present specification, the following aspects are provided.

### (Aspect 1)

Aspect 1 is a probe card including:
an insulating layer;
a first conductor at least partially extending along a surface of the insulating layer; and
a second conductor at least partially penetrating at least a portion of the insulating layer.

According to Aspect 1, the length of the first conductor can be shorter than that in a case where the first conductor penetrates the insulating layer. Accordingly, the transmission losses of the signal transmitted through the first conductor between the electronic device and the tester can be reduced as compared with a case where the first conductor penetrates the insulating layer. According to Aspect 1, the decrease of the number of signals transmitted through the second conductor between the electronic device and the tester can be prevented as compared with a case where the second conductor extends along the surface of the insulating layer.

### (Aspect 2)

Aspect 2 is the probe card according to Aspect 1,
in which the insulating layer includes a base region where at least a portion of the second conductor is provided, and an extension region where at least a portion of the first conductor is provided, the extension region being drawn from the base region.

According to Aspect 2, having the thickness of the extension region be thinner than the thickness of the base region can make the flexibility of the extension region higher than the flexibility of the base region. The shape of the extension region can be therefore deformed into an appropriate shape. The deformation of the shape of the extension region into an appropriate shape enables the first conductor to be drawn from the base region toward an appropriate position along the extension region.

### (Aspect 3)

Aspect 3 is the probe card according to Aspect 1 or 2, further including:
a probe head including a plurality of probes electrically connected to the first conductor and the second conductor, and an insulating support supporting the plurality of probes.

According to Aspect 3, when the plurality of probes can be individually inserted and removed with respect to the insulating support and fault such as wear requires the replacement of some of the probes among the plurality of probes, only faulted probe can be replaced without need to replace the entire probe head. In a case such as when using a flexible substrate such as FPC provided with a plurality of probes is used, on the other hand, there is a case where fault on some probes requires replacement of all of the plurality of probes because the plurality of probes cannot be individually replaced. According to Aspect 3, the maintaining cost of the probe card can be reduced as compared with such a case.

### (Aspect 4)

Aspect 4 is the probe card according to Aspect 1, further including:
a flexible substrate including at least a portion of the insulating layer, at least a portion of the first conductor, and at least a portion of the second conductor.

According to Aspect 4, the distance between the first conductor and the electronic device can be shorter than that in a case where the pogo-pin type probe card is used. Accordingly, the transmission losses of the signal transmitted between the first conductor and the electronic device can be reduced as compared with a case where the probe card is used.

### (Aspect 5)

Aspect 5 is the probe card according to any one of Aspects 1 to 4,
in which the first conductor transmits a signal of a first frequency, and
the second conductor transmits at least one of a direct current signal and a signal of a second frequency lower than a frequency of the first frequency.

According to Aspect 5, the transmission losses of the signal of the first frequency transmitted through the first conductor between the electronic device and the tester can be reduced as compared with a case where the first conductor penetrates the insulating layer. According to Aspect 1, the decrease of the number of direct current signals and signals of the second frequency transmitted through the second conductor between the electronic device and the tester can be prevented as compared with a case where the second conductor extends along the surface of the insulating layer.

This application claims priority based on Japanese Patent Application No. 2021-123029 filed on Jul. 28, 2021, the disclosure of which is incorporated herein in its entirety by reference.

### REFERENCE SIGNS LIST

10A, 10B probe card, 20 electronic device, 22 electrode, 30 tester, 32 first RF connector, 34 second RF connector, 36 DC/LF connector, 100 rigid substrate, 102 first through-hole, 104 second through-hole, 110 first connection conductor, 112 first via, 114 first wiring, 200A probe head, 200B flexible substrate, 210A probe, 210B second insulating layer, 212B second base region, 214B third extension region, 216B fourth extension region, 220A insulating support, 222B fourth transmission conductor, 224B fifth transmission conductor, 230B sixth transmission conductor, 300A first interposer, 300B second interposer, 310A first insulating layer, 310B third insulating layer, 312A first base region, 314A first extension region, 316A second extension region, 322A first transmission conductor, 324A second transmission conductor, 330A third transmission conductor, 330B second connection conductor, 332A, 332B second via, 334A, 334B second wiring, 350 bump, 400 stiffener, 410 first coaxial connector, 412 first holder, 420 second coaxial connector, 422 second holder, 430 first coaxial cable, 440 second coaxial cable, 500B anisotropic conductive rubber, 510B connection portion, X first direction, Y second direction, Z third direction

1. A probe card comprising:
an insulating layer;
a first conductor at least partially extending along a surface of the insulating layer; and
a second conductor at least partially penetrating at least a portion of the insulating layer.

2. The probe card according to claim 1,
wherein the insulating layer includes a base region where at least a portion of the second conductor is provided, and an extension region where at least a portion of the first conductor is provided, the extension region being drawn from the base region.

3. The probe card according to claim 1, further comprising:
a probe head including a plurality of probes electrically connected to the first conductor and the second conductor, and an insulating support supporting the plurality of probes.

4. The probe card according to claim 2, further comprising:
a probe head including a plurality of probes electrically connected to the first conductor and the second conductor, and an insulating support supporting the plurality of probes.

5. The probe card according to claim 1, further comprising:
a flexible substrate including at least a portion of the insulating layer, at least a portion of the first conductor, and at least a portion of the second conductor.

6. The probe card according to claim 1,
wherein the first conductor transmits a signal of a first frequency, and
the second conductor transmits at least one of a direct current signal and a signal of a second frequency lower than the first frequency.
